(19) United States
(12) Patent Application Publication
(10) Pub. No.: US 2008/0283111 A1
(43) Pub. Date: Nov. 20, 2008

(54) Solar Cell Module Connector

(75) Inventors: Makoto Higashikozono, Yokkaichi-shi (JP); Kazuki Naito, Yokkaichi-shi (JP)

Correspondence Address: OLIFF & BERRIDGE, PLC, P.O. BOX 320850, ALEXANDRIA, VA, 22320-4850, US

(73) Assignee: SUMITOMO WIRING SYSTEMS, LTD., Yokkaichi-shi (JP)

(21) Appl. No.: 11/664,524

(22) PCT Filed: Oct. 20, 2005
(86) PCT No.: PCT/JP05/19329

§ 371 Date: Apr. 3, 2007

(30) Foreign Application Priority Data
Nov. 16, 2004 (JP) 2004-332163

(51) Int. Cl. H01L 31/05

(52) U.S. Cl. 136/244

(57) ABSTRACT

The present invention includes two pairs of positive and negative cables are led out by dividing a pair of positive and negative terminals of a solar cell modules, and dipole connectors to which terminals are connected are formed on ends of the cables. The terminals in the dipole connector disposed on one side of the solar cell module form positive and negative plugs, while the terminals in the other dipole connector disposed on the other side of the solar cell module form positive and negative sockets. The cables include an inverse connection preventing portion which allows connection between the dipole connectors on a plug and socket side disposed between each adjacent solar cell modules when the polarities of the negative and positive terminals are the same, but which restricts connection therebetween when the polarities of the negative and positive terminals differ from each other.

### TECHNICAL FIELD

The present invention relates to a solar cell module connector used to connect a plurality of solar cell modules.

### BACKGROUND ART

A solar power generation system supplies direct currents from a solar cell panel installed on a house roof to electric appliances via a device such as an inverter. The solar cell panel is constituted by a plurality of solar cell modules which are connected to each other via connectors connected to ends of cables.

A solar power generation system formed by connecting a plurality of solar cell modules in parallel with each other is known (see, for example, patent document 1 shown below). A solar power generation system of this kind has a structure in which, as shown in FIG. 17A, a pair of positive and negative cables 2 and another pair of positive and negative cables 2 diverging from a pair of positive and negative terminals of a solar cell module 1 are led out, positive connectors 3 and negative connectors 4 are attached to ends of the cables 2, and, as shown in FIG. 17B, the positive connector 3 of this solar cell module 1 is connected to the positive connector 3 of an adjacent solar cell module 1 and the negative connector 4 of this solar cell module 1 is connected to the negative connector 4 of the adjacent solar cell module 1, thus successively connecting solar cell modules 1.

In this case, the positive connectors 3 and the negative connectors 4 comprise plugs (denoted by “P” in the figure) and sockets (denoted by “S” in the figure), and one combination of a plug and a socket are provided on opposite side of each solar cell module 1. If a plurality of solar cell modules 1 arranged in the direction of connections therebetween (the horizontal direction in FIG. 17B) is assumed to be one group, the solar power generation system 1 is divided into a plurality of groups (in the top-bottom direction of FIG. 17B) and output terminals from the groups are combined and connected to a power conditioner or the like.

[Patent document 1] Japanese Patent Laid-Open No. 8-46231

In the above-described case, the positive connectors 3 are formed so as to be identical in shape and size to each other; the negative connectors 4 are also formed so as to be identical in shape and size to each other; and the plugs and sockets are positioned close to each other in each adjacent upper-lower pair of the groups, as indicated by arrows in FIG. 17B. Therefore, there is a possibility of a connection being erroneously made between the positive and negative terminals in each group as well as between the groups.

The present invention has been completed in view of the above-described circumstances, and an object of the present invention is to avoid the occurrence of an erroneous connection between connectors not to be mated with each other.

### DISCLOSURE OF THE INVENTION

The invention set forth in claim 1 as a means for achieving the above-described object is characterized by having a plurality of solar cell modules connected in parallel with each other, pairs of positive and negative cables led out by dividing a pair of positive and negative terminals of each of the solar cell modules, positive and negative plugs which are terminals connected to ends of the cables, and which are disposed on one side of each solar cell module, positive and negative sockets which are terminals also connected to ends of the cables, which are disposed on the other side of each solar cell module, and which can be respectively connected to the plugs, a plug-side dipole connector including the positive and negative plugs and formed at the ends of the cables, the plug-side dipole connector for connecting the plugs disposed on one side of one of the solar cell modules to the sockets disposed on the other side of another of the solar cell modules adjacent to the one of the solar cell modules, a socket-side dipole connector including the positive and negative sockets and formed at the ends of the cables, the socket-side dipole connector for connecting to the plugs disposed on one side of one of the solar cell modules the sockets disposed on the other side of another of the solar cell modules adjacent to the one of the solar cell modules, and an inverse connection preventing portion provided on the plug-side dipole connector and the socket-side dipole connector to enable connection between the two dipole connectors in a case where the polarities of the positive and negative terminals in each combination between the two dipole connectors are the same, and to restrict connection between the two dipole connectors in a case where the polarities of the positive and negative terminals in each combination between the two dipole connectors differ from each other.

The invention set forth in claim 2 is characterized in that, in the arrangement set forth in claim 1, the inverse connection preventing portion comprises projections projecting from surfaces of the plug-side dipole connector and the socket-side dipole connector opposed to each other, and in that the two projections are in a non-interfering state in the case where the polarities of the positive and negative terminals in each combination are the same, and collide against each other in the case where the polarities of the positive and negative terminals in each combination differ from each other.

The invention set forth in claim 3 is characterized in that, in the arrangement set forth in claim 2, the dipole connector has a clamp for connecting together the positive connector and the negative connector constituting the dipole connector, and the projection projects from an end surface of the clamp.

The invention set forth in claim 4 is characterized in that, in the arrangement set forth in claim 3, the clamp is constituted by a pair of divided members capable of pinching the positive connector and the negative connector in a peripheral direction and divisible from each other, and the projection is formed on only one of the divided members.

The invention set forth in claim 5 is characterized in that, in the arrangement set forth in claim 1, the inverse connection preventing portion comprises a flexible lock portion provided in one of the plug-side dipole connector and the socket-side dipole connector, and a lock receiving portion provided on the other dipole connector, and in that the lock portion is elastically engageable with the lock receiving portion only when the polarities of the positive and negative terminals in each combination are the same and when the two dipole connectors reach the normal connection position.

The invention set forth in claim 6 is characterized in that, in the arrangement set forth in claim 5, the lock portion and the lock receiving portion are provided in only one of the positive and negative connectors constituting the dipole connector.

The invention set forth in claim 7 is characterized in that, in the arrangement set forth in claim 1, the inverse connection preventing portion comprises offset portions formed by shifting in the axial direction the end positions of the positive connector and the negative connector constituting the dipole connector, and in that fitting between the offset portions can be performed when the polarities of the positive and negative terminals are the same, and cannot be performed when the polarities of the positive and negative terminals differ from each other.

The invention set forth in claim 8 is characterized in that, in the arrangement set forth in claim 7, the dipole connector has a clamp which connects together the positive connector and the negative connector constituting the dipole connector, and the offset portions are formed on the basis of a stepped form of the clamp.

### <Claim 1>

The dipole connectors are connected to ends of cables led out from the pair of positive and negative terminals of each solar cell module, the terminals in the dipole connector disposed on one side of the solar cell module form positive and negative plugs, and the terminals in the dipole connector disposed on the other side of the solar cell module form positive and negative sockets. In a case where a plurality of solar cell modules aligned with each other in row and column directions are connected in parallel with each other to form one group in a horizontal direction for example, the two dipole connectors opposed to each other in the column direction are in a plug-to-plug relationship or in a socket-to-socket relationship. Therefore, the occurrence of erroneous connection between the two dipole connectors between groups can be avoided.

The plug-side dipole connector and the socket-side dipole connector has an inverse connection preventing portion for restricting connection in a case where the polarities of the positive and negative terminals in combination between the two dipole connectors differ from each other. Therefore, the occurrence of erroneous connection between the two dipole connectors opposed to each other in the horizontal direction in each group can also be avoided.

### <Claim 2>

The inverse connection preventing portion comprises projections. Two projections are in a non-interfering state in a case where the polarities of the positive and negative terminals are the same, and collide against each other in a case where the polarities of the positive and negative terminals differ from each other. Thus, inverse connection between the two dipole connectors in each group can be prevented with reliability by a comparative simple method.

### <Claim 3>

The projections project from end surfaces of the clamps (surfaces of the plug-side dipole connector and the socket-side dipole connector opposed to each other). Therefore, prevention of inverse connection can be achieved without changing the structures of the existing positive and negative connectors.

### <Claim 4>

The clamp is constituted by a pair of divided members and the projection is formed on only one of the divided members. Therefore, the structure of one of the two divided members can be simplified.

### <Claim 5>

The inverse connection preventing portion comprises a flexible lock portion provided in one of the plug-side dipole connector and the socket-side dipole connector, and a lock receiving portion provided on the other dipole connector, and the lock portion is elastically engageable with the lock receiving portion only when the polarities of the positive and negative terminals in each combination are the same and when the two dipole connectors reach the normal connection position. Therefore, the function to lock the two dipole connectors can include an inverse connection prevention function.

### <Claim 6>

The lock portion and the lock receiving portion are provided in only one of the positive and negative connectors constituting the dipole connector. Therefore, the need to provide a lock structure on the other connector can be eliminated to simplify the structure.

### <Claim 7>

The inverse connection preventing portion comprises offset portions formed by shifting in the axial direction the end positions of the positive connector and the negative connector constituting the dipole connector, and fitting between the offset portions can be performed only when the polarities of the positive and negative terminals are the same. Therefore, it is not necessary to add a separate member for prevention of inverse connection to the dipole connector. Simplification of the structure can be achieved in this way.

### <Claim 8>

The offset portions are formed on the basis of a stepped form of the clamp. Therefore, prevention of inverse connection can be achieved without changing the structure of the existing positive and negative connectors.

### BRIEF DESCRIPTION OF THE DRAWINGS

FIG. 1 is a side view of a state in which a connector according to Embodiment 1 of the present invention is connected to positive and negative terminals of a solar cell module;

FIG. 2 is a side view of the connectors before connection;

FIG. 3 is a side view of the connectors connected together;

FIG. 4 is a sectional view of the connectors before connection;

FIG. 5 is a sectional view of the connectors connected together;

FIG. 6 is a front view of the connector on the socket side;

FIG. 7 is a front view of the connector on the plug side;

FIG. 8 is a wiring diagram showing a state in which a plurality of solar cell modules are connected in parallel with each other;

FIG. 9 is a side view of connectors before connection in Embodiment 2 of the present invention;

FIG. 10 is a side view of the connectors connected together;

FIG. 11 is a front view of the connector on the socket side;

FIG. 12 is a front view of the connector on the plug side;

FIG. 13 is a side view of connectors before connection in Embodiment 3 of the present invention;

FIG. 14 is a side view of the connectors connected together;

FIG. 15 is a front view of the connector on the socket side;

FIG. 16 is a front view of the connector on the plug side;

FIG. 17A is a diagram schematically showing a state in which connectors are connected to ends of two pairs of positive and negative cables in the conventional art; and

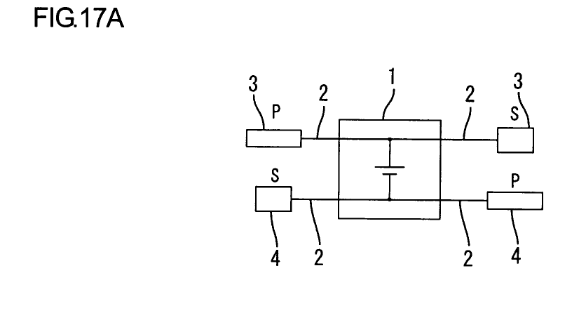

FIG. 17B is a wiring diagram showing a state in which a plurality of solar cell modules are connected in parallel with each other in the conventional art.

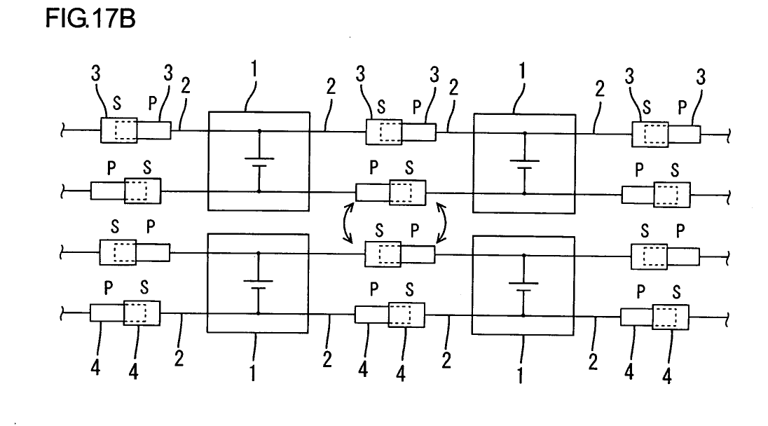

### DESCRIPTION OF SYMBOLS

11 Cable
20 Dipole connector
21 Positive connector
22 Negative connector
23 Clamp
24 Fitting tubular portion
27 Lock portion
28 Lock lug
31 Hood portion
32 Lock receiving portion
37 Projection

### BEST MODE FOR CARRYING OUT THE INVENTION

### Embodiment 1

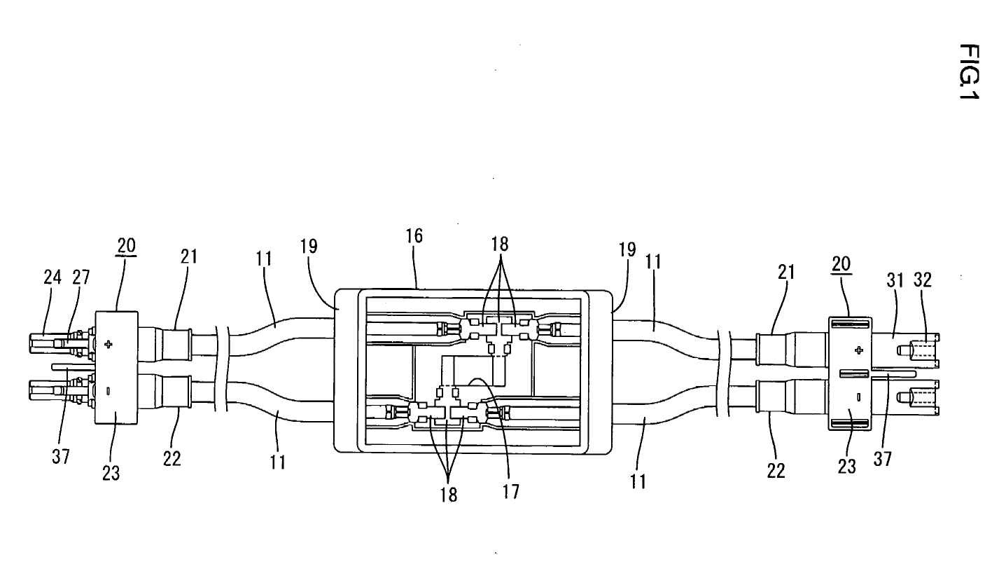

Embodiment 1 of the present invention will be described with reference to FIGS. 1 to 8. In this embodiment, two pairs of positive and negative cables 11, i.e., one pair of positive and negative cables 11 and another pair of positive and negative cables 11, are led out by dividing a pair of positive and negative terminals from a solar cell module 10, and a dipole connector 20 having terminals 15 connected to ends of the cables 11 led out is integrally formed. A plurality of solar cell modules 10 are disposed in matrix form, i.e., in alignment with each other in row and column directions, and are connected in parallel with each other.

A terminal box 16 is attached to the back surface (the surface opposite from the glass surface) of the solar cell module 10, as shown in FIG. 1. A pair of positive and negative leads (not shown) from the solar cell module 10 are led into the terminal box 16 through an opening 17. Ends of the leads are connected to pairs of positive and negative relay terminals 18 in the terminal box 16. The cables 11 are connected to the relay terminals 18 and are extended as separate pairs of positive and negative cables in opposite directions from left and right side walls 19 of the terminal box 16. Terminals 15 are connected to the extension ends of the cables 11. Each pair of positive and negative terminals 15 are connected to a corresponding pair of positive and negative connectors 21 and 22, and the pair of connectors 21 and 22 are integrally combined with each other by a clamp 23, thus forming left and right pairs of dipole connectors 20.

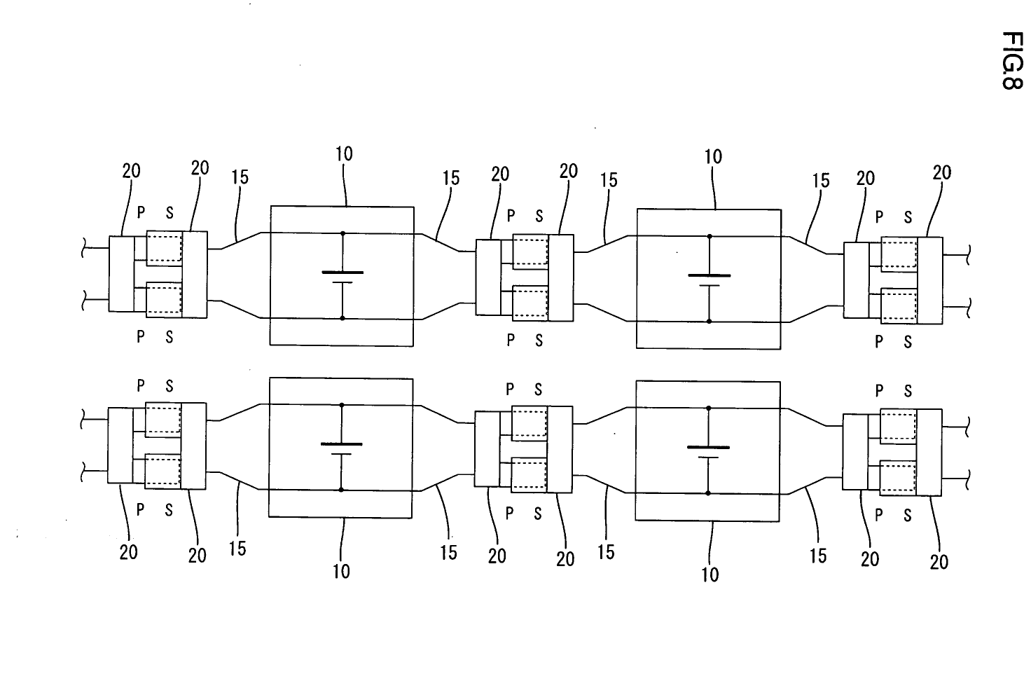

In the terminals 15 connected to the extension ends of the cables 11, each of the positive and negative ones in one of the left and right pairs of dipole connectors 20 (disposed on the right-hand side of the terminal box as viewed in FIG. 1) is a plug (denoted by “P” in FIG. 8), while each of the positive and negative ones in the other of the left and right pairs of dipole connectors 20 (disposed on the left-hand side of the terminal box as viewed in FIG. 1) is a socket (denoted by “S” in FIG. 8).

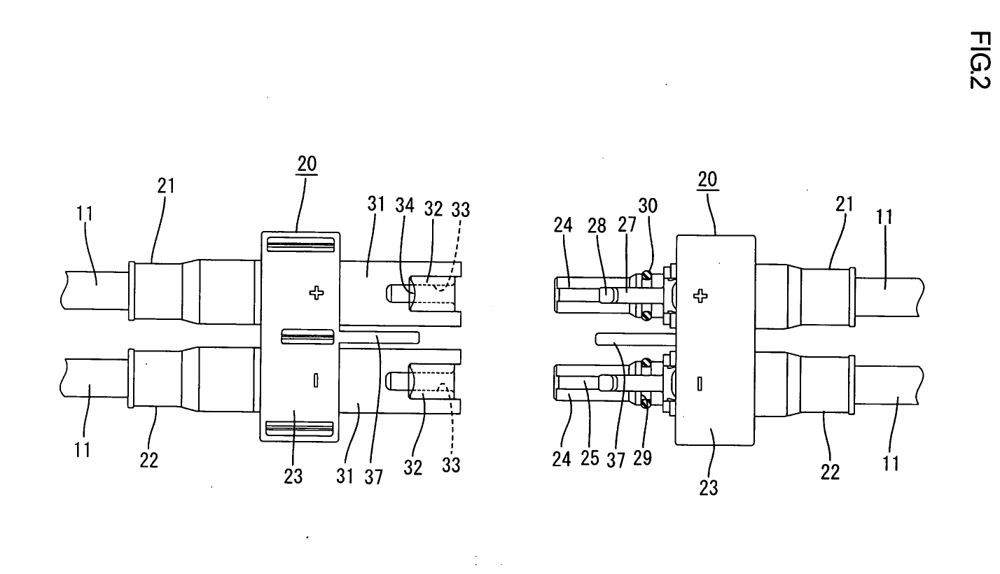

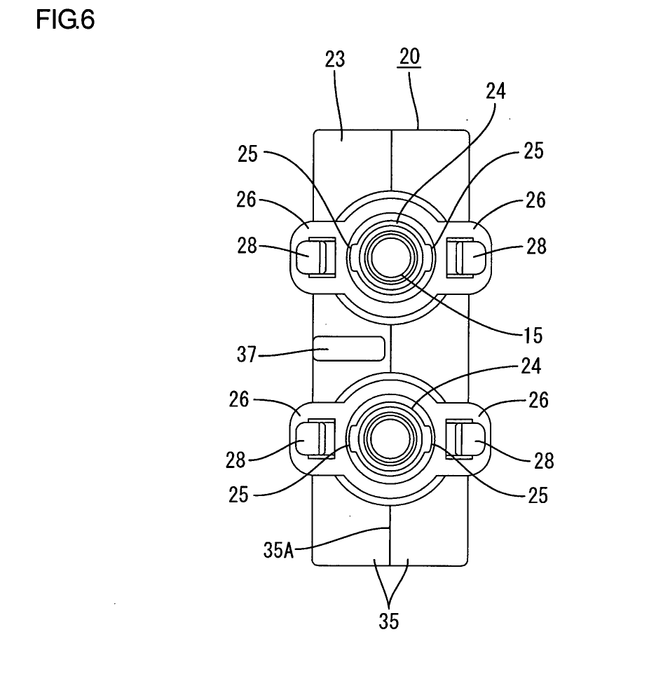

As shown in FIG. 2 on the right-hand side and in FIG. 6, the other of the dipole connector 20 is constituted by the positive connector 21 and the negative connector 22 on the socket side and the clamp 23 connecting together these connectors in parallel with each other. The positive connector 21 and the negative connector 22 are formed so as to be identical in shape and size to each other.

Each of the positive connector 21 and the negative connector 22 on the socket side has a fitting tubular portion 24 coaxially surrounding a cylindrical socket and made of a synthetic resin, and a root portion of the socket is attached to an inner wall of the fitting tubular portion 24. Axial guide ribs 25 are formed on an outer peripheral surface of the fitting tubular portion 24 on left and right sides of the same by being extended. A pair of left and right protuberant portions 26 are formed on the outer peripheral surface of the fitting tubular portion 24 on left and right sides and on the rear end side (cable 11 connection side) of the same. A pair of left and right lock portions 27 generally parallel to the outer peripheral surface of the fitting tubular portion 24 are formed so as to project frontward from front end surfaces of the protuberant portions 26. The lock portions 27 are in cantilever form and are flexibly deformable radially. A lock lug 28 is formed projecting outward on a front end portion of each lock portion 27. A seal groove 29 in which a seal ring 30 is fitted is provided in each fitting tubular portion 24 at a position closer to the front end relative to the protuberant portion 26.

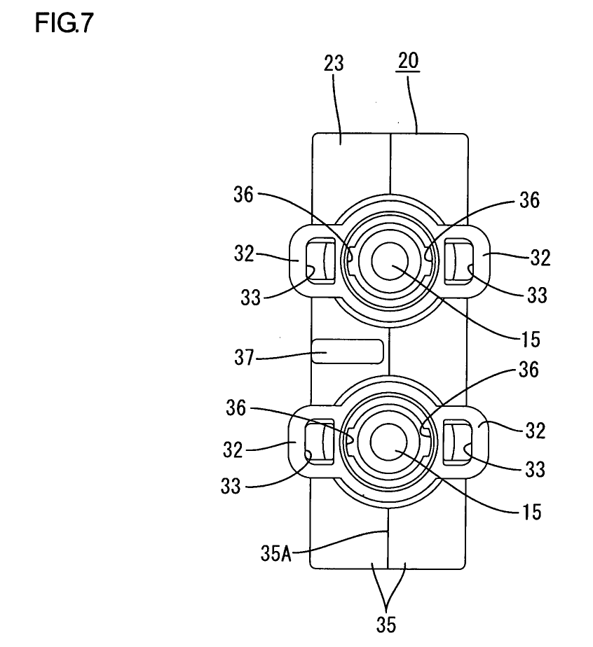

As shown in FIG. 2 on the left-hand side and in FIG. 7, the one of the dipole connectors 20 is constituted by the positive connector 21 and the negative connector 22 on the plug side and the clamp 23 connecting together these connectors in parallel with each other. The positive connector 21 and the negative connector 22 are formed so as to be identical in shape and size to each other, as are those described above.

Each of the positive connector 21 and the negative connector 22 on the plug side is in the form of a cylinder as a whole and has a cylindrical hood portion 31 coaxially surrounding a cylindrical plug. A root portion of the plug is attached to an inner wall of the hood portion 31. The inside diameter of the hood portion 31 is set to such a value that the fitting tubular portion 24 on the socket side can be tightly fitted. Guide channels 36 engageable with the guide rib 25 are formed in an inner peripheral surface of the hood portion 31 on left and right sides of the same by being extended in the axial direction. The seal ring 30 on the socket side is brought into close contact with the inner peripheral surface of the hood portion 31 to effect sealing.

A pair of left and right lock receiving portions 32 capable of elastically engaging with the lock portion 27 on the socket side are formed in the hood portion 31 on left and right sides and on the front end side of the same. Each lock receiving portion 32 is in the form of a tunnel as a whole and has an escapement hole 33 formed therethrough in the front-rear direction. The lock portion 27 can be passed through the escapement hole 33 while being elastically bent inwardly. A rear end surface of each lock receiving portion 32 is formed as a receiving surface 34 capable of elastically engaging with the lock lug 28 of the lock portion 27 at the time of normal fitting to the socket. More specifically, in the process of fitting the two dipole connectors 20 on the plug and socket sides, the lock lugs 28 of the lock portions 27 advance inside the escapement holes 33 of the lock receiving portions 32 while being elastically bent. When the two dipole connectors 20 reach the normally fitted position, the lock lugs 28 move apart from the escapement holes 33 and the lock portions 27 elastically restore the original shape. Simultaneously, the lock lugs 28 face the receiving surface 34 in the axial direction and lock the two dipole connectors 20 in a disengagement stopped state. A setting is made to ensure that, in the process of fitting the two dipole connectors 20, positioning in the circumferential direction is performed by sliding the guide ribs 25 in the guide channels 36 to enable engagement between the lock portion 27 and the lock receiving portion 32.

The clamp 23 on the plug side is formed of a synthetic resin and has, as shown in FIG. 7, such a construction as to be divided into left and right divided members 35. The two divided members 35 have their joint edges 35A fitted to each other from the left and right sides while the pair of positive and negative connectors 21 and 22 are arranged in the longitudinal direction to pitch and hold the two connectors 21 and 22 therebetween. In this case, the two divided members 35 are jointed in a one-touch manner based on the elastic engagement action therebetween.

On a front end surface of the divided member 35 disposed on the left-hand side as viewed in FIG. 7 in the two divided members 35, a projection 37 is formed substantially at a central position in the height direction so as to project frontward. The projection 37 is disposed between the pair of positive and negative connectors 21 and 22 and has a sectional shape elongated in the lateral direction. When the pair of positive and negative connectors 21 and 22 are pinched between the two divided members 35, the front end positions of the two connectors 21 and 22 are aligned with each other and the front end of the projection 37 is set at a position recessed from the front end positions of the two connectors 21 and 22.

The clamp 23 on the socket side has an internal structure different from that of the clamp 23 on the plug side but has an external form substantially identical in shape and size to that of the clamp 23 on the plug side. Also, the clamp 23 on the socket side is constituted by left and right divided members 35 joinable to each other, as described above. On a front end surface of the divided member 35 disposed on the left-hand side as viewed in FIG. 6 in the two divided members 35, a projection 37 is formed substantially at a central position in the height direction so as to project frontward. The projection 37 may alternatively be provided on the front end surface of each of the divided members 35 disposed on the right-hand sides as viewed in FIGS. 6 and 7.

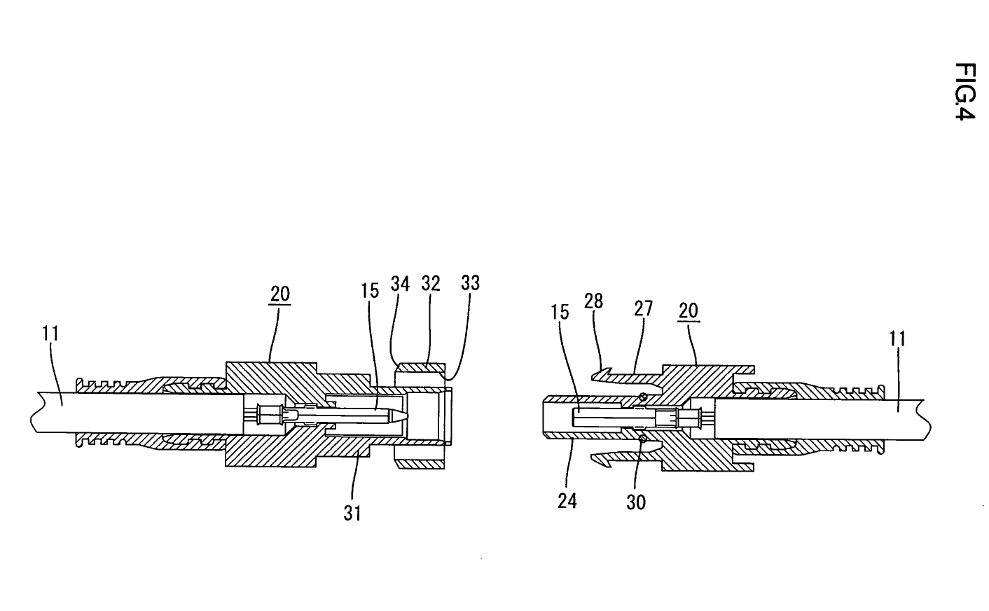

In a case where a group in which a plurality of solar cell modules 10 are connected in parallel with each other is formed, that is, those arranged horizontally as viewed in FIG. 8 in a plurality of solar cell modules disposed in alignment with each other in row and column directions form one group, the dipole connector 20 on the plug side and the dipole connector 20 on the socket side are opposed to each other in the horizontal direction between each adjacent pair of the solar cell modules 1.0 in the group, as shown in FIGS. 2 and 4. In this case, when, as shown in FIG. 2, the two dipole connectors 20 are set in the respective normal connection attitudes, and when the polarities of the terminals facing each other in each combination are the same, the end of the projection 37 on the plug side is opposed to the front end surface of the divided member 35 on which no projection 37 exists in the clamp 23 on the socket side, while the end of the projection 37 on the socket side is opposed to the front end surface of the divided member 35 on which no projection 37 exists in the clamp 23 on the plug side. Thus, the two projections 37 are in a non-interfering positional relationship with each other. Consequently, plug-socket connections can be made between the positive poles and between the negative poles.

In contrast, when one of the two dipole connectors 20 is in the inverted attitude, and when the polarities of the terminals facing each other in each combination differ from each other, the end of the projection 37 on the plug side and the end of the projection 37 on the socket side are in such a positional relationship as to abut against each other, and plug-socket connection is impossible between the different polarities.

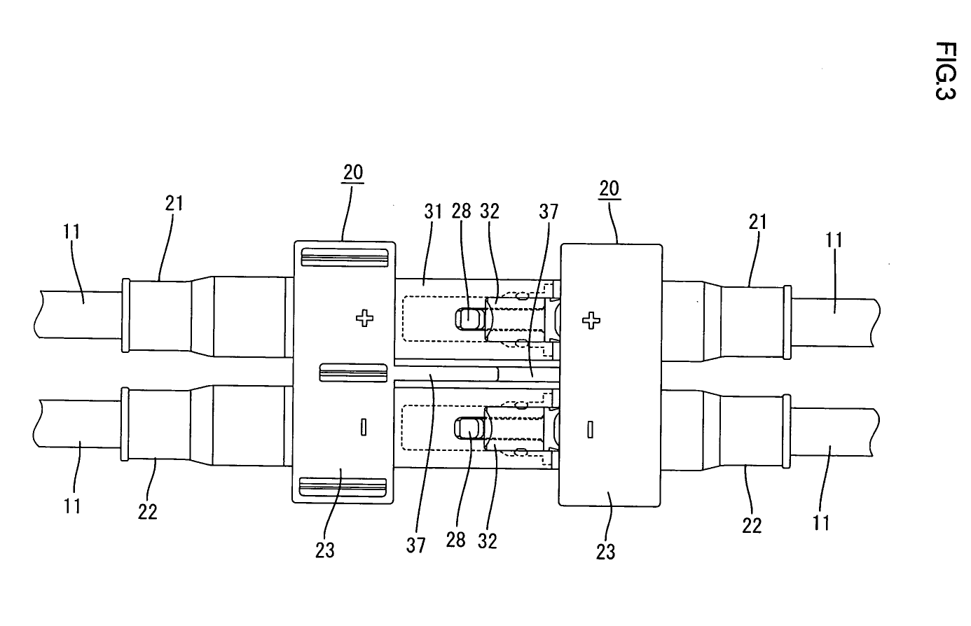

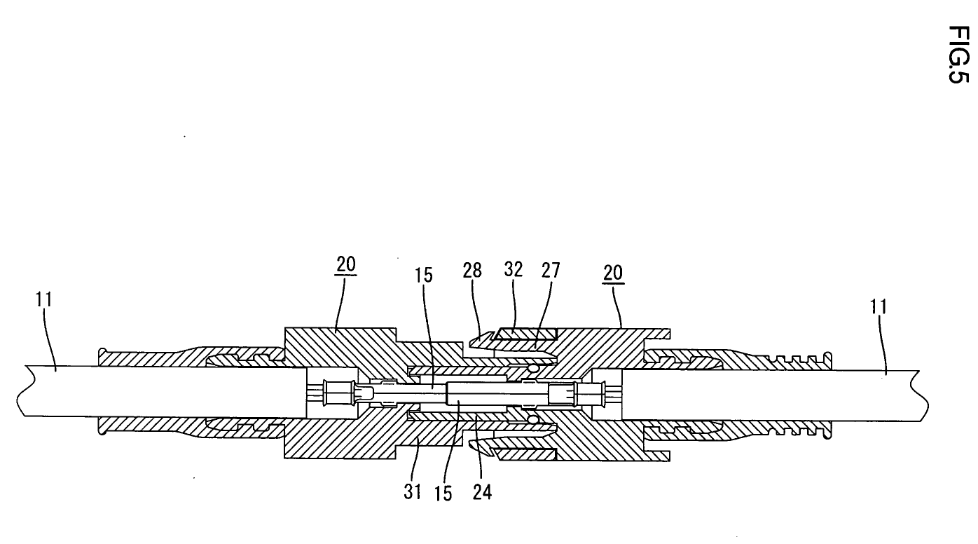

More specifically, between the positive connector 21 on the plug side and the positive connector 21 on the socket side and between the negative connector 22 on the plug side and the negative connector 22 on the socket side (as shown in FIGS. 3 and 5), the fitting tubular portions 24 are normally fitted in the hood portions 31 to enable the plug to be inserted in the socket through the normal depth and to enable the lock portions 27 and the lock receiving portions 32 to elastically engage with each other to complete locking. In contrast, between the positive connector 21 on the plug side and the negative connector 22 on the socket side and between the negative connector 22 on the plug side and the positive connector 21 on the socket side, the two projections 37 collide against each other to stop the plug from being inserted before the lock portions 27 and the lock receiving portions 32 elastically engage with each other.

Thus, according to this embodiment, the two dipole connectors 20 disposed between an adjacent pair of solar cell modules 10 can be prevented from being connected in the inverted state. Since the inverse connection prevention function is performed on the basis of the shapes of the clamps 23, it is not necessary to specially change the shapes of the pair of positive and negative connectors 21 and 22.

Further, because two dipole connectors 20 opposed in the column direction between the groups are in a plug-to-plug or socket-to-socket relationship, erroneous connection between two dipole connectors 20 between the groups can be avoided.

### Embodiment 2

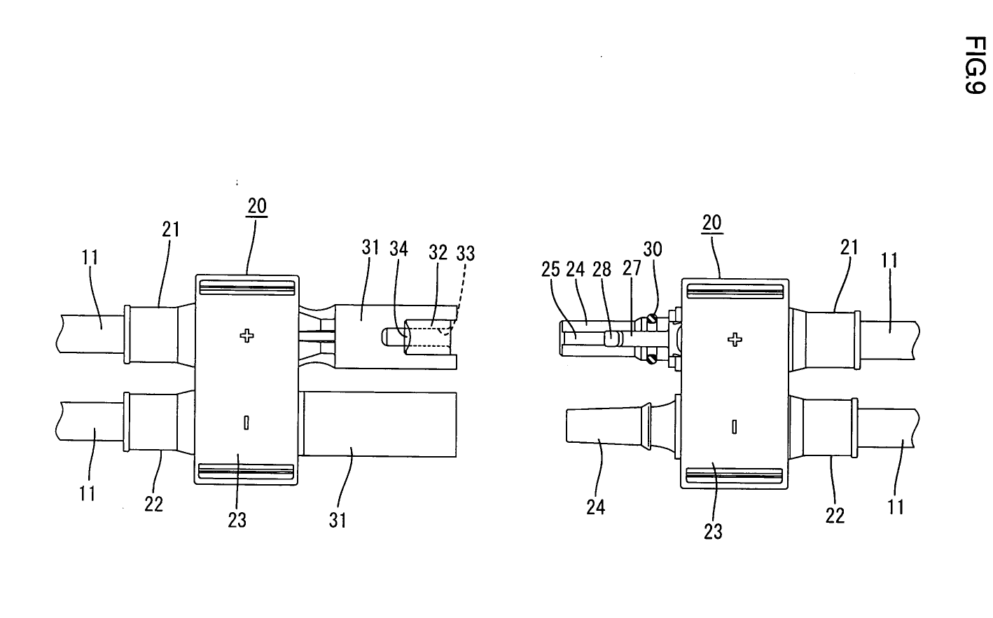

Embodiment 2 of the present invention will be described with reference to FIGS. 9 to 12. The forms of the dipole connectors 20 in Embodiment 2 differ from those in Embodiment 1. In other respects, Embodiment 2 is substantially the same as Embodiment 1. A redundant description in relation to the description of Embodiment 1 will not be made. Structural portions identical or corresponding to those in Embodiment 1 are indicated by the same reference numerals.

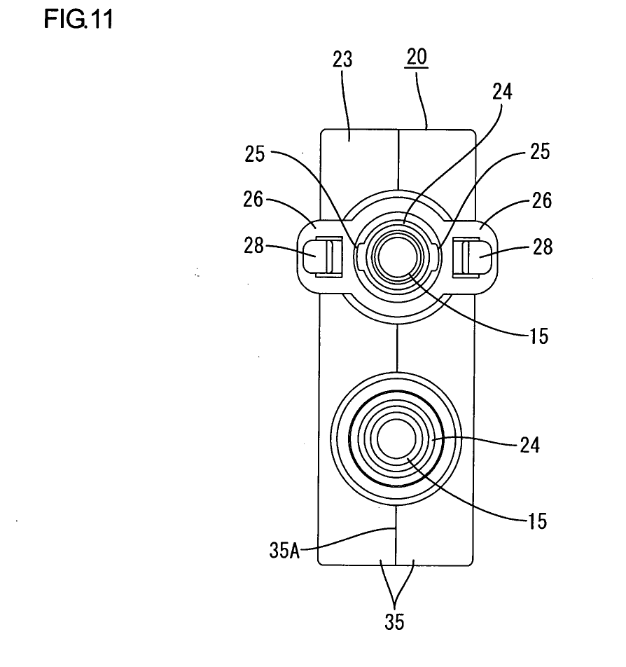

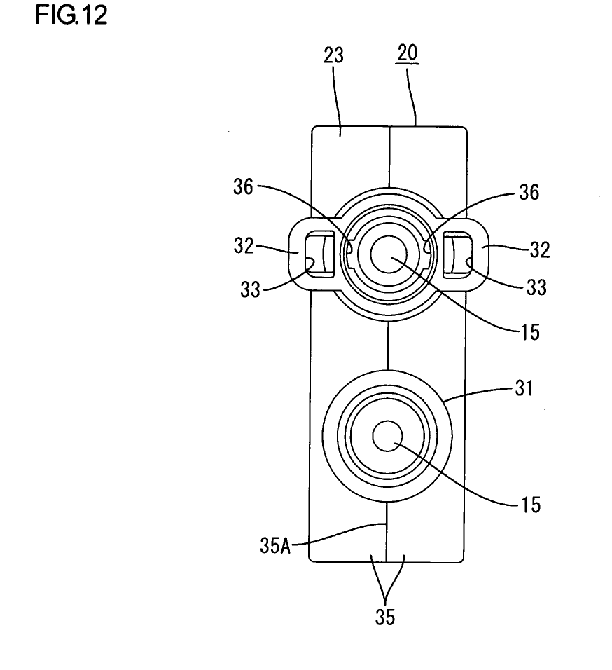

In Embodiment 2, the forms of the positive connector 21 and the negative connector 22 constituting each dipole connector 20 are made different from each other to prevent inverse connection between the two dipole connectors 20 disposed between each adjacent pair of solar cell modules 10. More specifically, a construction described below is provided. As shown in FIG. 9 on the right-hand side and in FIG. 11, the protuberant portions 26 and the lock portions 27 in Embodiment 1 are formed on the positive connector 21 on the socket side, but the protuberant portions 26 and the lock portions 27 are not formed on the positive connector 22 on the socket side. Also, as shown in FIG. 9 on the left-hand side and in FIG. 12, the lock receiving portions 32 in Embodiment 1 are formed on the positive connector 21 on the plug side, but the lock receiving portions 32 are not formed on the positive connector 22 on the plug side. The projection 37 in Embodiment 1 is not provided on each of the clamps 23 on the plug and socket sides. Thus, the structures of the negative connectors 22 on the plug and socket sides are simplified.

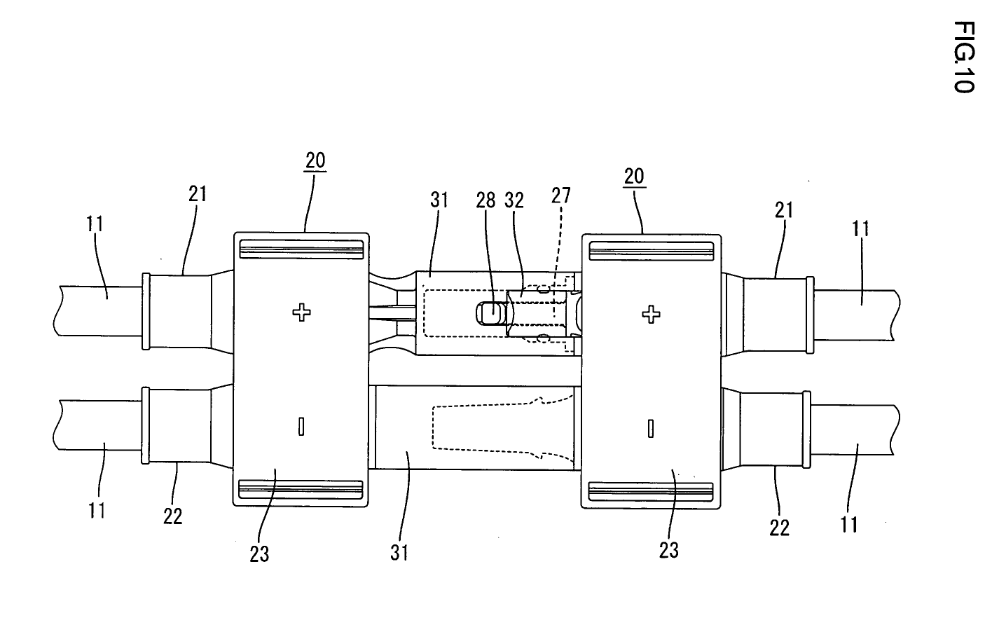

According to Embodiment 2, when the two dipole connectors 20 disposed between an adjacent pair of solar cell modules 10 are in the normal connection attitudes, the plug is inserted in the socket through the normal depth and the lock portions 27 elastically engage with the lock receiving portions 32 with the completion of this insertion, as shown in FIG. 10, thus enabling locking of the two dipole connectors 20. When one of the two dipole connectors 20 is in the inverted attitude, the lock portions 27 and the lock receiving portions 32 are in a non-interfering relationship even after the plug has been inserted in the socket. The two dipole connectors 20 are not locked in this case. That is, inverse connection between the two dipole connectors 20 can be detected according to the locked/nonlocked state of the two dipole connectors 20. The arrangement may alternatively be such that the protuberant portions 26 and the lock portions 27 are provided in the negative connector 22 on the socket side, while the lock receiving portions 32 are provided in the negative connector 22 on the plug side. The arrangement may alternatively be such that the protuberant portions 26 and the lock portions 27 are provided in the negative connector 22 on the plug side, while the lock receiving portions 32 are provided in the negative connector 22 on the socket side. Further, the arrangement may alternatively be such that the protuberant portions 26 and the lock portions 27 are provided in the positive connector 21 on the plug side, while the lock receiving portions 32 are provided in the positive connector 21 on the socket side.

### Embodiment 3

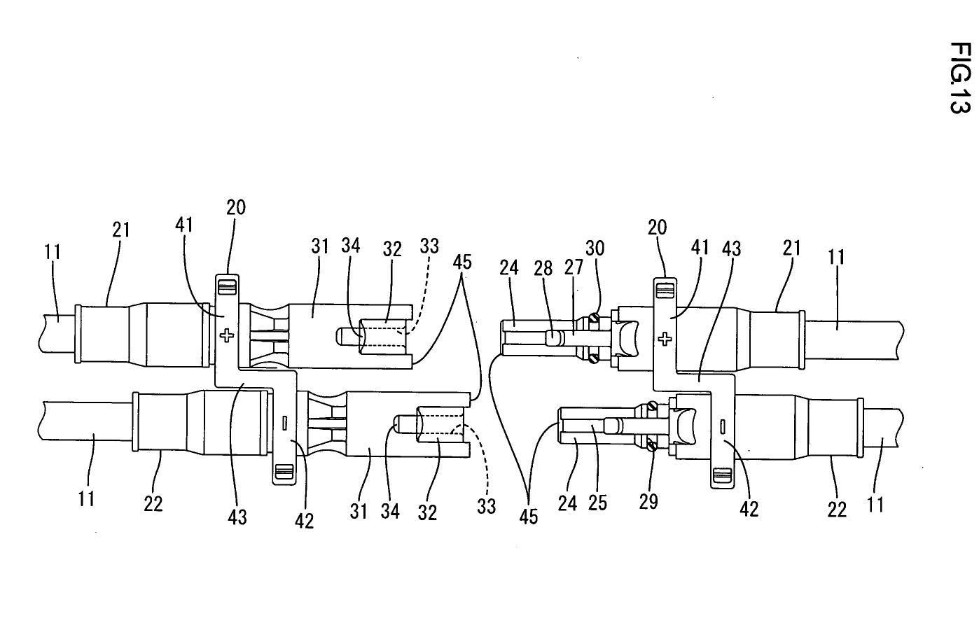

Embodiment 3 of the present invention will be described with reference to FIGS. 13 to 16. The form of clamps 23 in the dipole connectors 20 in Embodiment 3 differs from that in Embodiment 1. In other respects, Embodiment 3 is substantially the same as Embodiment 1. Structural portions identical or corresponding to those in Embodiment 1 are indicated by the same reference numerals.

Embodiment 3 has the same positive connectors 21 and negative connectors 22 as those in Embodiment 1, and pairs of connectors 21 and 22 are fitted in clamps 23 to prevent inverse connection between two dipole connectors 20 disposed between each adjacent pair of solar cell modules 10. That is, as shown in FIG. 13, the clamp 23 on the plug side and the clamp 23 on the socket side in the clamps 23 in Embodiment 3 are identical to each other, and each clamp 23 has a holding portion 41 on the positive connector 21 side for holding the positive connector 21, and a holding portion 42 on the negative connector 22 side for holding the negative connector 22. The clamp 23 is constructed in such a manner that the two holding portions 41 and 42 extend in a direction perpendicular to the axial direction; the positions of the two holding portions 41 and 42 are shifted from each other in the axial direction; and the upper and lower ends of the two holding portions 41 and 42 are connected to each other by an intermediate connection portion 43 extending in the axial direction.

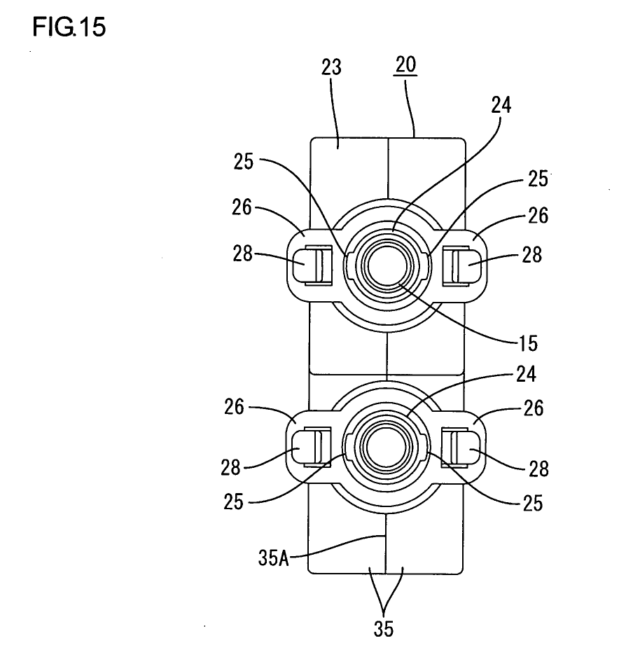

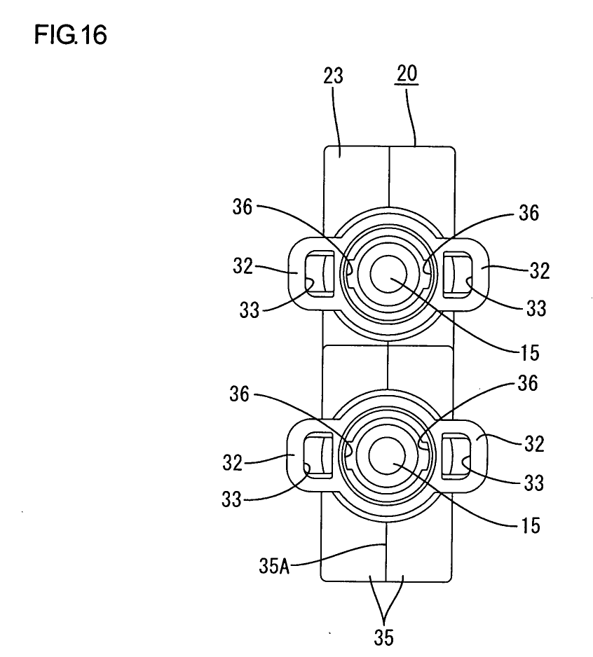

As shown in FIGS. 15 and 16, the clamp 23 is constituted by a pair of left and right divided members 35, and the positive and negative connectors 21 and 22 are pinched by combining the two divided members 35. When the two connectors 21 and 22 are held in the thus-constructed clamp 23 at a position generally at a center in the longitudinal direction, the end positions of the two connectors 21 and 22 are shifted from each other in the axial direction, thereby forming offset portions 45 in stepped form on front end surfaces of the dipole connectors 20. More specifically, in the dipole connector 20 on the plug side, the end position of the negative connector 22 is set frontward relative to the end position of the positive connector 21. In the dipole connector 20 on the socket side, the end position of the positive connector 21 is set frontward relative to the end position of the negative connector 22. The amounts of positional shift on the plug and socket sides are set substantially equal to each other.

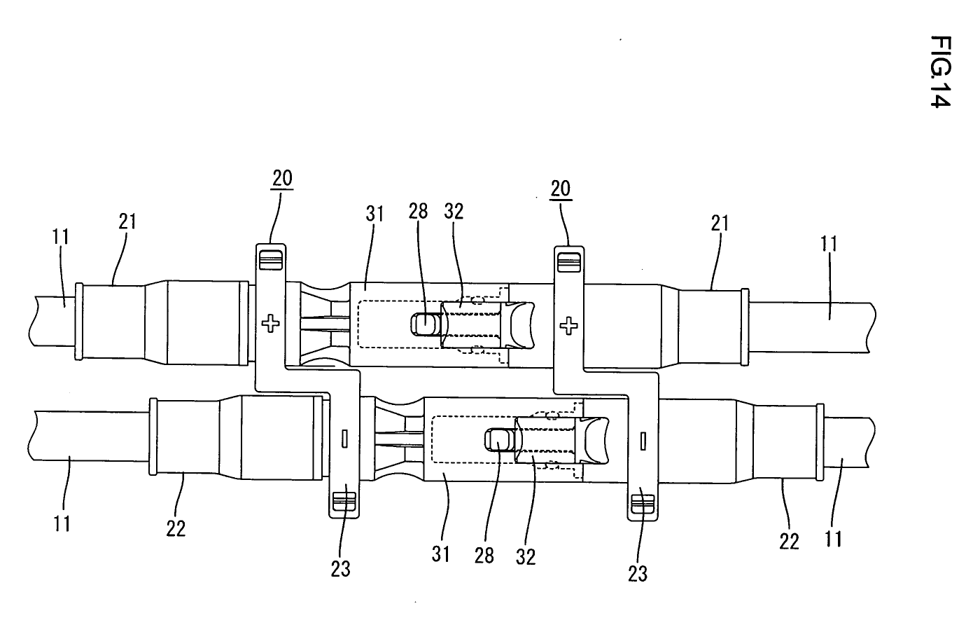

According to Embodiment 3, when the two dipole connectors 20 on the plug and socket sides disposed between each adjacent pair of solar cell modules 10 are opposed to each other by being set in the respective normal connection attitudes, and when the polarity of the terminals facing each other in each combination are the same, as shown in FIG. 14, the two offset portions 45 formed on the two dipole connectors 20 are in such a relationship as to fit to each other, thereby allowing the plug to be inserted in the socket through the normal depth. Thus, connection between the two dipole connectors 20 is enabled. In contrast, when one of the two dipole connectors 20 is in the inverted attitude, and when the polarities of the terminals facing each other in each combination differ from each other, fitting between the two offset portions 45 is restricted to restrict the connection between the two dipole connectors 20. Since this inverse connection prevention function is performed on the basis of the shapes of the clamps 23, it is not necessary to specially change the shapes of the pair of positive and negative connectors 21 and 22.

### Other Embodiments

The present invention is not limited to the above-described embodiments. For example, embodiments described below are included in the technical scope of the present invention, and various changes other than those described below may be made and implemented without departing from the scope of the invention.
(1) While projections are provided as inverse connection preventing portions on the clamps in Embodiment 1 described above, a projection may be provided as an inverse connection preventing portion on one of the two positive and negative connectors according to the present invention.
(2) While each dipole connector is constituted by a pair of positive and negative connectors to which terminals are attached and a clamp in Embodiments 1 to 3, each dipole connector may be formed by integrally forming a pair of positive and negative connectors from a synthetic resin material without using a clamp according to the present invention described above.

1-8. (canceled)

9. A solar cell module connector comprising:
a plurality of solar cell modules connected in parallel with each other;
a pair of positive and negative cables extending from at least two sides the plurality of solar cell modules;
positive and negative plugs extending from ends of the cables and disposed on one side of each of the plurality of solar cell modules;
positive and negative sockets extending from ends of the cables and disposed on the other side of each of the plurality of solar cell modules, and which can be respectively connected to the plugs;
a plug-side dipole connector including the positive and negative plugs, the plug-side dipole connector for connecting the plugs disposed on one side of one of the solar cell modules to the sockets disposed on the other side of another of the solar cell modules adjacent to the one of the plurality of solar cell modules;
a socket-side dipole connector including the positive and negative sockets, the socket-side dipole connector for connecting to the plugs disposed on one side of one of the solar cell modules the sockets disposed on the other side of another of the solar cell modules adjacent to the one of the plurality of solar cell modules; and
an inverse connection preventing portion provided on the plug-side dipole connector and the socket-side dipole connector to enable connection between the plugs and sockets that have the same polarity, and to restrict connection between the plugs and sockets having a different polarity.

10. The solar cell module connector according to claim 9, wherein the inverse connection preventing portion includes projections projecting from surfaces of the plug-side dipole connector and the socket-side dipole connector opposed to each other, further wherein the projections are in a non-interfering state in the case where the polarities of the plugs and sockets to be connected are the same, and collide against each other in the case where the polarities of the plugs and sockets to be connected differ from each other.

11. The solar cell module connector according to claim 10, wherein each of the plug-side and socket-side dipole connector has a clamp for connecting together a positive connector and a negative connector of each of the plug-side and socket side dipole connector, further wherein the projection extend from an end surface of the clamp.

12. The solar cell module connector according to claim 11, wherein the clamp includes a pair of divided members capable of pinching the positive connector and the negative connector in a peripheral direction and divisible from each other, and the projection is formed on only one of the divided members.

13. The solar cell module connector according to claim 9, wherein the inverse connection preventing portion includes a flexible lock portion provided in one of the plug-side dipole connector and the socket-side dipole connector, and a lock receiving portion provided on the other dipole connector, further wherein the lock portion is elastically engageable with the lock receiving portion only when the polarities of the plugs and sockets are the same.

14. The solar cell module connector according to claim 9, wherein the inverse connection preventing portion includes offset portions formed by shifting in the axial direction end positions of each of the positive and negative plugs and each of the positive and negative sockets, further wherein fitting between the offset portions can be performed when the polarities of the plugs and sockets are the same, and cannot be performed when the polarities of the plugs and sockets differ from each other.

15. The solar cell module connector according to claim 14, wherein each of the plug-side and socket-side dipole connector has a clamp, and the offset portions are formed as stepped from the clamp.

16. A connector system comprising:
a first cable extending from a side of a first connector, the first cable including a plug-side dipole connector having a positive and negative plug extending from an end of the first cable;
a second cable extending from a side of a second connector, the second cable including a socket-side dipole connector having a positive and negative socket extending from an end of the second cable, wherein sockets are capable of connection to the plugs;
an inverse connection preventing portion provided on the plug-side dipole connector and the socket-side dipole connector to enable connection between the plugs and sockets that have a same polarity, and to restrict connection between the plugs and sockets having a different polarity.

17. The connector system according to claim 16, wherein the inverse connection preventing portion includes projections extending from a surface of the plug-side dipole connector and a surface of the socket-side dipole connector, further wherein the projections are in a non-interfering state when the polarities of the plugs and sockets to be connected are the same, and collide against each other when the polarities of the plugs and sockets to be connected differ from each other.

18. The connector system according to claim 17, wherein each of the plug-side and socket-side dipole connector include a clamp for connecting together a positive connector and a negative connector of each of the plug-side and socket side dipole connector, further wherein the projection extends from an end surface of the clamp.

19. The connector system according to claim 18, wherein the clamp includes a pair of divided members capable of pinching the positive connector and the negative connector in a peripheral direction

20. The connector system according to claim 19, wherein the divide members are divisible from each other.

21. The connector system according to claim 19, wherein the projection is formed on only one of the divided members.

22. The connector system according to claim 16, wherein the inverse connection preventing portion includes a flexible lock portion provided in one of the plug-side dipole connector and the socket-side dipole connector, and a lock receiving portion provided on the other dipole connector, further wherein the lock portion is elastically engageable with the lock receiving portion only when the polarities of the plugs and sockets are the same.

23. The connector system according to claim 16, wherein the inverse connection preventing portion includes the plug-side dipole connector structure so that the plugs are offset from each other.

24. The connector system according to claim 23, wherein the inverse connection prevention portion includes the socket-side dipole connector structured so that the sockets are offset from each other.

25. The connector system according to claim 24, wherein fitting between the plugs and sockets can be performed when the polarities of the plugs and sockets are the same, and cannot be performed when the polarities of the plugs and sockets differ from each other.

26. The connector system according to claim 25, wherein each of the plug-side and socket-side dipole connector has a clamp, and the plugs and sockets are positioned to be stepped from of the clamp.
